(19) United States
(12) Patent Application Publication
(10) Pub. No.: US 2026/0070320 A1
(43) Pub. Date: Mar. 12, 2026

(54) PAD FOR LAMINATION AND METHOD OF MANUFACTURING DISPLAY DEVICE

(71) Applicant: Samsung Display Co., LTD., Yongin-si (KR)

(72) Inventors: JINHYUK PARK, Yongin-si (KR); KYOUNGDUCK KIM, Yongin-si (KR); JONG-NAM LEE, Yongin-si (KR); JONGSUK LEE, Yongin-si (KR); SEUNGJIN LIM, Yongin-si (KR)

(21) Appl. No.: 19/175,244

(22) Filed: Apr. 10, 2025

(30) Foreign Application Priority Data
Sep. 9, 2024 (KR) 10-2024-0122301

(51) Int. Cl. B32B 37/10; H10H 29/01; H10H 29/85

(52) U.S. Cl. CPC B32B 37/10; H10H 29/036; H10H 29/8506; B32B 2457/20

(57) ABSTRACT

A pad for lamination includes a first pad which applies a first pressure to a first area of a display panel, and a second pad which is at least partially surrounded by the first pad in a plan view and which applies a second pressure to a second area different from the first area of the display panel. After the first pad fixes at least a portion of the first area of the display panel, the second pad stretches the second area of the display panel, such that a display device may be manufactured in which defects such as, for example, wrinkles of the display panel which may occur in a lamination process are minimized in quantity or reduced in size.

This application claims priority to Korean Patent Application No. 10-2024-0122301, filed on Sep. 9, 2024, and all the benefits accruing therefrom under 35 U.S.C. § 119, the content of which in its entirety is herein incorporated by reference.

### BACKGROUND

### 1. Field

Embodiments relate to a pad and a method of manufacturing a display device. More specifically, embodiments relate to a pad for lamination and a method of manufacturing a display device using the pad.

### 2. Description of the Related Art

A display device may include a display panel and a window which protects the display panel. The display panel and the window may be coupled to each other by a lamination process, and a pressing member such as, for example, a silicone pad may be used to closely contact the display panel with the protection window.

### SUMMARY

Embodiments provide a pad for lamination which improves defects in a display device.

Embodiments provide a method of manufacturing a display device using the pad.

A pad for lamination according to an embodiment of the present disclosure includes a first pad which applies a first pressure to a first area of a display panel, and a second pad which is at least partially surrounded by the first pad in a plan view and applies a second pressure to a second area different from the first area of the display panel.

In an embodiment, the first area may be an edge area of the display panel, and the second area may be a central area of the display panel.

In an embodiment, the first pad and the second pad may be spaced apart from each other.

In an embodiment, the first pad may have a first hardness, and the second pad may have a second hardness different from the first hardness.

In an embodiment, the first pad may have a first friction coefficient, and the second pad may have a second friction coefficient different from the first friction coefficient.

In an embodiment, the first pad may completely surround the second pad in the plan view.

In an embodiment, the first pad may define an opening exposing at least a portion of a side surface of the second pad.

In an embodiment, the first pad and the second pad may sequentially apply the first pressure and the second pressure to the display panel.

A method of manufacturing a display device according to an embodiment of the present disclosure includes arranging a pad for lamination on a window, wherein the pad includes a first pad which applies a first pressure to a first area of a display panel and a second pad which applies a second pressure to a second area different from the first area of the display panel, and the display panel is arranged between the pad and the window, applying a first pressure to the first area of the display panel with the first pad, wherein applying the first pressure bonds the first area of the display panel and the window, and applying a second pressure to the second area of the display panel with the second pad, wherein applying the second pressure bonds the second area of the display panel and the window.

In an embodiment, the applying of the first pressure to the first area of the display panel with the first pad and the applying of the second pressure to the second area of the display panel with the second pad may be sequentially performed.

In an embodiment, the first area may be an edge area of the display panel, and the second area may be a central area of the display panel.

In an embodiment, in the applying of the first pressure to the first area of the display panel with the first pad, the first area of the display panel may be fixed to the window by the first pad.

In an embodiment, in the applying of the second pressure to the second area of the display panel with the second pad, the second area of the display panel may be stretched by the second pad and bonded to the window.

In an embodiment, the first pad may surround at least a portion of the second pad in a plan view.

In an embodiment, the first pad may completely surround the second pad in a plan view.

In an embodiment, the first pad may define an opening exposing at least a portion of a side surface of the second pad.

In an embodiment, the first pad may have a first hardness, and the second pad may have a second hardness different from the first hardness.

In an embodiment, the first pad may have a first friction coefficient, and the second pad may have a second friction coefficient different from the first friction coefficient.

In an embodiment, the applying of the second pressure to the second area of the display panel with the second pad may include tilting the second pad in association with applying the second pressure to the second area of the display panel.

In an embodiment, the window may have a dome shape convexly curved in a direction.

In a pad for lamination according to embodiments of the present disclosure, the pad may include a first pad and a second pad at least partially surrounded by the first pad in a plan view. After at least a portion of an edge area of a display panel is bonded to a window using the first pad, a central area of the display panel may be bonded to the window using the second pad. After the first pad fixes at least a portion of the edge area of the display panel, the second pad stretches the central area of the display panel, such that a display device may be manufactured in which defects such as, for example, wrinkles of the display panel which may occur in a lamination process are minimized in quantity or reduced in size.

### BRIEF DESCRIPTION OF THE DRAWINGS

FIGS. 1A and 1B are views illustrating a pad for lamination according to an embodiment of the present disclosure.

FIGS. 2A and 2B are views illustrating a pad for lamination according to an embodiment of the present disclosure.

FIG. 3 is an exploded perspective view illustrating an example of a display device manufactured using a pad for lamination according to an embodiment of the present disclosure.

FIG. 4 is a cross-sectional view of a portion of a display panel included in the display device of FIG. 3.

FIGS. 5, 6, 7A, 7B, and 8 are cross-sectional views illustrating a method of manufacturing a display device according to an embodiment of the present disclosure.

### DETAILED DESCRIPTION

Hereinafter, embodiments of the present disclosure will be described in more detail with reference to the accompanying drawings. The same reference numerals are used for the same components in the drawings, and redundant descriptions of the same components will be omitted.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as, for example, “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

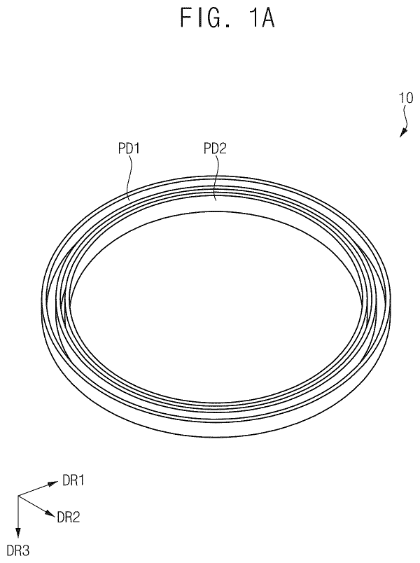

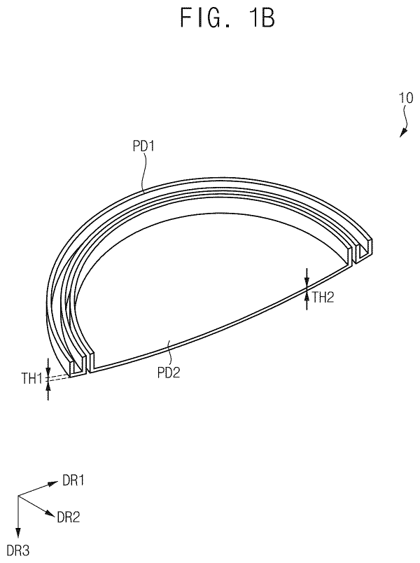

FIGS. 1A and 1B are views illustrating a pad for lamination according to an embodiment of the present disclosure. For example, FIG. 1A may be a perspective view illustrating a pad 10 for lamination, and FIG. 1B may be a perspective view illustrating a cross-section taken from the pad 10 of FIG. 1A in a first direction DR1.

Referring to FIGS. 1A and 1B, the pad 10 may extend parallel to a plane defined by the first direction DR1 and a second direction DR2 intersecting the first direction DR1. The pad 10 may be movable in a third direction DR3 intersecting each of the first direction DR1 and the second direction DR2 and in a direction opposite to the third direction DR3.

The pad 10 may be used in a manufacturing process of a display device. For example, the pad 10 may be used in a lamination process in the manufacturing process of the display device. For example, the pad 10 may be moved in the third direction DR3 in association with bonding a first object and a second object. For example, embodiments of the present disclosure include moving the pad 10 using equipment (not illustrated) or manual techniques during the manufacturing process. In an example, the first object may be a display panel included in the display device, and the second object may be a window included in the display device which protects the display panel.

In an embodiment, the pad 10 may include silicone. For example, the pad 10 may be formed by curing a silicone resin. However, embodiments of the present disclosure are not limited thereto, and the pad 10 may include other elastic materials.

The pad 10 may include a first pad PD1 and a second pad PD2. The first pad PD1 may surround at least a portion of the second pad PD2 in a plan view.

In an embodiment, the first pad PD1 may surround an entirety of the second pad PD2 in a plan view. The first pad PD1 may completely surround the second pad PD2 in a plan view. For example, the first pad PD1 may entirely cover a side surface of the second pad PD2. For example, the first pad PD1 may extend continuously outside the second pad PD2. In a plan view, the second pad PD2 may have a shape accommodated in the first pad PD1.

In an embodiment, the second pad PD2 may have a circular shape in a plan view, and the first pad PD1 may have a hollow circular shape surrounding the second pad PD2 in a plan view. However, embodiments of the present disclosure are not limited thereto. For example, the second pad PD2 may have various shapes such as, for example, a polygonal shape, an elliptical shape, or the like in a plan view, and the first pad PD1 may have various shapes surrounding the second pad PD2 in a plan view and corresponding to the shape of the second pad PD2 (e.g., a hollow polygonal shape, a hollow elliptical shape, or the like).

When the pad 10 bonds the first object (e.g., a display panel) and the second object (e.g., a window), the first pad PD1 and the second pad PD2 may respectively apply pressure to different areas of the first object. In an embodiment, the first pad PD1 may apply pressure to an edge area of the first object, and the second pad PD2 may apply pressure to a central area other than the edge area of the first object. For example, the first pad PD1 may be moved in the third direction DR3 in association with bonding the edge area of the first object and the second object, and the second pad PD2 may be moved in the third direction DR3 in association with bonding the central area of the first object and the second object. In an embodiment, the first pad PD1 and the second pad PD2 may independently apply a respective pressure to the first object.

In an embodiment, at least a portion of an upper surface of each of the first pad PD1 and the second pad PD2 may be recessed in the third direction DR3. A minimum thickness of the first pad PD1, which is defined by recessing at least a portion of an upper surface of the first pad PD1, may be defined as a first thickness TH1, and a minimum thickness of the second pad PD2, which is defined by recessing at least a portion of an upper surface of the second pad PD2, may be defined as a second thickness TH2. That is, the first thickness TH1 may be defined as a minimum length of the first pad PD1 in the third direction DR3, and the second thickness TH2 may be defined as a minimum length of the second pad PD2 in the second direction DR2.

For example, a central portion of the upper surface of the first pad PD1 may be recessed in the third direction DR3, such that the first pad PD1 may have a ‘U’-shape in a cross-sectional view, and in this case, a thickness in the third direction DR3 of a bottom portion of the ‘U’-shape in a cross-sectional view may be defined as the first thickness TH1. In an embodiment, the first thickness TH1 may be about 0.5 millimeters (mm) or less, and preferably, the first thickness TH1 may be about 0.3 mm or less.

However, embodiments of the present disclosure are not limited thereto, and the shape or thickness of the first pad PD1 may be variously modified. For example, the first pad PD1 may have an ‘L’-shape in a cross-sectional view, and the first thickness TH1 may be variously modified to a thickness which supports the first pad PD1 fixing the first object to which the first pad PD1 applies pressure.

In some aspects, for example, a central portion of the upper surface of the second pad PD2 may be recessed in the third direction DR3, such that the second pad PD2 may have a ‘U’-shape in a cross-sectional view, and in this case, a thickness in the third direction DR3 of a bottom portion of the ‘U’-shape in a cross-sectional view may be defined as the second thickness TH2. In an embodiment, the second thickness TH2 may be about 0.5 mm or less.

However, embodiments of the present disclosure are not limited thereto, and the shape or thickness of the second pad PD2 may be variously modified. For example, the second pad PD2 may have a ‘-’-shape in a cross-sectional view, and the second thickness TH2 may be variously modified to a thickness which supports the second pad PD2 stretching (or applying tension to) the first object to which the second pad PD2 applies pressure.

The first pad PD1 may have a first hardness, and the second pad PD2 may have a second hardness. The first hardness and the second hardness may be different from each other. In an embodiment, the first hardness may be greater than the second hardness. For example, the first hardness may be 70 Shore A hardness or greater, and the second hardness may be 50 Shore A hardness or greater, but embodiments of the present disclosure are not limited thereto.

The first pad PD1 may have a first friction coefficient, and the second pad PD2 may have a second friction coefficient. The first friction coefficient and the second friction coefficient may be different from each other. In an embodiment, the first friction coefficient may be greater than the second friction coefficient. For example, the first pad PD1 may have an unprocessed surface, and the second pad PD2 may have a processed surface. For example, the first friction coefficient may be 0.9 or greater, and the second friction coefficient may be 0.3 or greater, but embodiments of the present disclosure are not limited thereto.

In an embodiment, the first pad PD1 and the second pad PD2 may be spaced apart from each other. That is, the first pad PD1 and the second pad PD2 may be separate components. In this case, for example, the first pad PD1 and the second pad PD2 may be relatively close to each other (e.g., based on distance) but separate from each other. However, embodiments of the present disclosure are not limited thereto, and for example, the first pad and the second pad PD2 may be integrally formed.

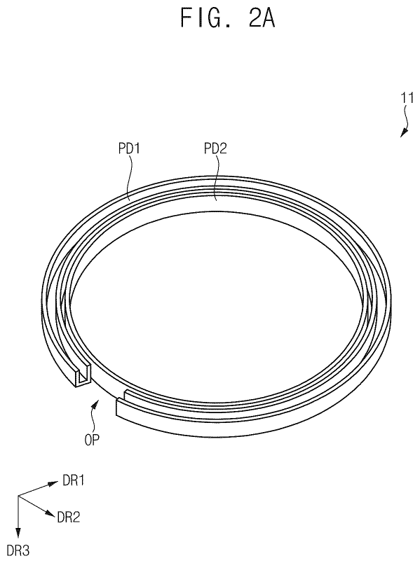

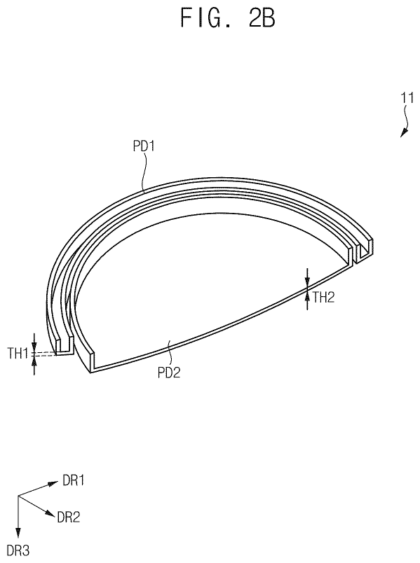

FIGS. 2A and 2B are views illustrating a pad for lamination according to an embodiment of the present disclosure. For example, FIG. 2A may be a perspective view illustrating a pad 11 for lamination, and FIG. 2B may be a perspective view illustrating a cross-section taken from the pad 11 of FIG. 2A in the first direction DR1.

The pad 11 described with reference to FIGS. 2A and 2B may be substantially the same as or similar to the pad 10 described with reference to FIGS. 1A and 1B, except for the shape of the first pad PD1. Hereinafter, redundant descriptions will be omitted or simplified.

Referring to FIGS. 2A and 2B, the pad 11 may extend parallel to the plane defined by the first direction DR1 and the second direction DR2, and may be movable in the third direction DR3 and the direction opposite to the third direction DR3.

The pad 11 may be used in a manufacturing process of a display device. For example, the pad 11 may be used in a lamination process in the manufacturing process of the display device. For example, the pad 11 may be moved in the third direction DR3 in association with bonding a first object and a second object.

In an embodiment, the pad 11 may include silicon. The pad 11 may include a first pad PD1 and a second pad PD2. The first pad PD1 may surround at least a portion of the second pad PD2 in a plan view.

In an embodiment, the first pad PD1 may partially surround the second pad PD2 in a plan view. In a plan view, the first pad PD1 may surround a portion of the second pad PD2, and may not surround another portion of the second pad PD2. For example, the first pad PD1 may partially cover a side surface of the second pad PD2. For example, the first pad PD1 may define an opening OP exposing at least a portion of the second pad PD2 (i.e., at least a portion of the side surface of the second pad PD2). The first pad PD1 may not continuously extend outside the second pad PD2, and may be disconnected.

In an embodiment, the second pad PD2 may have a circular shape in a plan view, and the first pad PD1 may have a shape in which a portion is removed (i.e., the opening OP is defined) from a hollow circle surrounding the second pad PD2 in a plan view (e.g., a ‘C’-shape)). However, embodiments of the present disclosure are not limited thereto. For example, the second pad PD2 may have various shapes such as, for example, a polygonal shape, an elliptical shape, or the like in a plan view, and the first pad PD1 may have various shapes surrounding the second pad PD2 in a plan view and corresponding to the shape of the second pad PD2 (e.g., a shape in which a portion is removed (i.e., the opening OP is defined) from a hollow polygon, a shape in which a portion is removed (i.e., the opening OP is defined) from a hollow ellipse, or the like).

When the pad 11 bonds the first object (e.g., a display panel) and the second object (e.g., a window), the first pad PD1 and the second pad PD2 may respectively apply pressure to different areas of the first object. In an embodiment, the first pad PD1 may apply pressure to an edge area (i.e., at least a portion of the edge area) of the first object, and the second pad PD2 may apply pressure to a central area other than the edge area of the first object. For example, the first pad PD1 may be moved in the third direction DR3 in association with bonding the edge area of the first object and the second object, and the second pad PD2 may be moved in the third direction DR3 in association with bonding the central area of the second object and the second object. In an embodiment, the first pad PD1 and the second pad PD2 may independently apply a respective pressure to the first object.

When the pad 11 bonds the first object and the second object, air bubbles which may occur between the first object and the second object may be minimized by the opening OP defined in the first pad PD1. For example, the first object may be a display panel of a display device, the second object may be a window of the display device, and the pad 11 may be used in a manufacturing process of the display device. In an example in which the pad 11 bonds the display panel and the window, air bubbles which may occur between the display panel and the window during the bonding process may be removed by the shape (i.e., the opening OP) of the first pad PD1. Accordingly, the display device in which air bubbles are minimized between the display panel and the window may be manufactured.

In an embodiment, at least a portion of an upper surface of each of the first pad PD1 and the second pad PD2 may be recessed in the third direction DR3. A minimum thickness of the first pad PD1, which is defined by recessing at least a portion of an upper surface of the first pad PD1, may be defined as a first thickness TH1, and a minimum thickness of the second pad PD2, which is defined by recessing at least a portion of an upper surface of the second pad PD2, may be defined as a second thickness TH2.

For example, a central portion of the upper surface of the first pad PD1 may be recessed in the third direction DR3, such that the first pad PD1 may have a ‘U’-shape in a cross-sectional view, and a thickness in the third direction DR3 of a bottom portion of the ‘U’-shape in a cross-sectional view may be defined as the first thickness TH1. In an embodiment, the first thickness TH1 may be about 0.5 mm or less, and preferably, the first thickness TH1 may be about 0.3 mm or less. However, embodiments of the present disclosure are not limited thereto, and the shape of the first pad PD1 and the first thickness TH1 may be variously modified.

In some aspects, for example, a central portion of the upper surface of the second pad PD2 may be recessed in the third direction DR3, such that the second pad PD2 may have a ‘U’-shape in a cross-sectional view, and a thickness in the third direction DR3 of a bottom portion of the ‘U’-shape in a cross-sectional view may be defined as the second thickness TH2. In an embodiment, the second thickness TH2 may be about 0.5 mm or less. However, embodiments of the present disclosure are not limited thereto, and the shape of the second pad PD2 and the second thickness TH2 may be variously modified.

The first pad PD1 may have a first hardness, and the second pad PD2 may have a second hardness. In an embodiment, the first hardness may be greater than the second hardness. For example, the first hardness may be 70 Shore A hardness or greater, and the second hardness may be 50 Shore A hardness or greater, but embodiments of the present disclosure are not limited thereto.

The first pad PD1 may have a first friction coefficient, and the second pad PD2 may have a second friction coefficient. In an embodiment, the first friction coefficient may be greater than the second friction coefficient. For example, the first pad PD1 may have an unprocessed surface, and the second pad PD2 may have a processed surface. For example, the first friction coefficient may be 0.9 or greater, and the second friction coefficient may be 0.3 or greater, but embodiments of the present disclosure are not limited thereto.

In an embodiment, the first pad PD1 and the second pad PD2 may be spaced apart from each other. That is, the first pad PD1 and the second pad PD2 may be separate components. In this case, for example, the first pad PD1 and the second pad PD2 may be relatively close to (e.g., based on distance) but separate from one another. However, embodiments of the present disclosure are not limited thereto, and for example, the first pad PD1 and the second pad PD2 may be integrally formed.

The lamination pad 10 and the pad 11 according to an embodiment of the present disclosure may include the first pad PD1 and the second pad PD2 at least partially surrounded by the first pad PD1 in a plan view. The first pad PD1 and the second pad PD2 may independently apply a respective pressure to different areas of the first object in association with bonding the first object and the second object. For example, the first pad PD1 may apply pressure to the edge area of the first object, and the second pad PD2 may apply pressure to the central area other than the edge area of the first object. Accordingly, defects such as, for example, wrinkles in the edge area of the first object which may occur in a lamination process may be minimized in quantity or reduced in size.

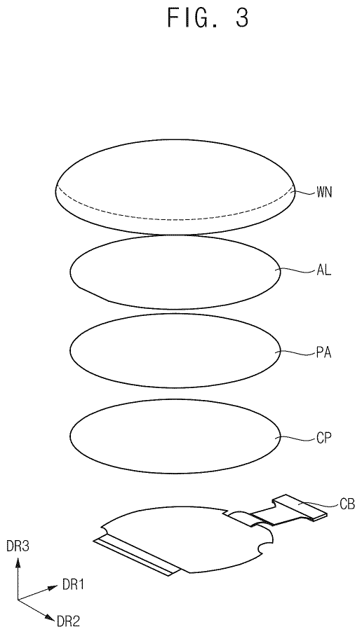

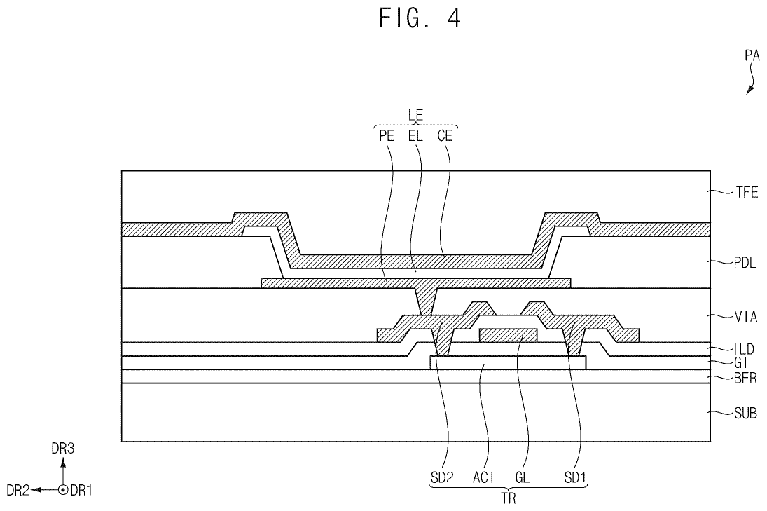

FIG. 3 is an exploded perspective view illustrating an example of a display device manufactured using a pad for lamination according to an embodiment of the present disclosure. FIG. 4 is a cross-sectional view of a portion of a display panel included in the display device of FIG. 3.

Referring to FIG. 3, a display device may include a window WN, an adhesive layer AL, a display panel PA, a cover panel CP, and a circuit board CB.

The cover panel CP, the display panel PA, the adhesive layer AL, and the window WN may be sequentially arranged on the circuit board CB. For example, the circuit board CB, the cover panel CP, the display panel PA, the adhesive layer AL, and the window WN may be sequentially arranged along the third direction DR3.

The window WN may protect components arranged below the window WN from external environment, impact, or the like. The window WN may be optically transparent. For example, the window WN may include glass, a transparent polymer material, or the like.

In an embodiment, the window WN may have a dome shape. For example, the window WN may have a dome shape which is convexly curved in the third direction DR3 in a cross-sectional view. An inner surface of the window WN may have a selected curvature, and the curvature may not be limited. As the window WN has a dome shape, the window WN may define an inner space. The window WN may accommodate components arranged below the window WN in the inner space.

The adhesive layer AL may be arranged below the window WN. The adhesive layer AL may couple the window WN and a component arranged below the adhesive layer AL. The adhesive layer AL may be optically transparent. For example, the adhesive layer AL may include an optically clear adhesive (OCA), an optically clear resin (OCR), or a pressure sensitive adhesive (PSA). Accordingly, influence of the adhesive layer AL on a visibility of an image generated from the display panel PA may be reduced.

The display panel PA may be arranged below the adhesive layer AL. For example, the display panel PA may be coupled to the window WN by the adhesive layer AL. The display panel PA may include pixels which emit light. Accordingly, the display panel PA may display an image, and the image displayed on the display panel PA may be provided outside the display device.

The display panel PA may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE. The transistor TR may include an active pattern ACT, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, the substrate SUB may include plastic, glass, quartz, silicon, or the like. These may be used alone or in combination with each other.

The buffer layer BFR may be arranged on the substrate SUB. The buffer layer BFR may prevent metal atoms, impurities, or the like from diffusing into the transistor TR. The buffer layer BFR may include an inorganic material such as, for example, silicon oxide (SiOₓ), silicon nitride (SiNₓ), silicon oxynitride (SiOₓN_{y}), or the like. These may be used alone or in combination with each other.

The active pattern ACT may be arranged on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

The gate insulating layer GI may be arranged on the active pattern ACT, and may cover the active pattern ACT. The gate insulating layer GI may include an inorganic material such as, for example, silicon oxide, silicon nitride, silicon oxynitride, or the like. These may be used alone or in combination with each other.

The gate electrode GE may be arranged on the gate insulating layer GI. The gate electrode GE may overlap the channel area of the active pattern ACT in a plan view. The gate electrode GE may include a metal, an alloy, a conductive metal oxide, a conductive metal nitride, a transparent conductive material, or the like. These may be used alone or in combination with each other.

The interlayer insulating layer ILD may be arranged on the gate electrode GE, and may cover the gate electrode GE. The interlayer insulating layer ILD may include an inorganic material such as, for example, silicon oxide, silicon nitride, silicon oxynitride, or the like. These may be used alone or in combination with each other.

The first and second electrodes SD1 and SD2 may be arranged on the interlayer insulating layer ILD. The first and second electrodes SD1 and SD2 may be connected to the source area and the drain area of the active pattern ACT, respectively. For example, each of the first electrode SD1 and the second electrode SD2 may include a metal, an alloy, a conductive metal oxide, a conductive metal nitride, a transparent conductive material, or the like. These may be used alone or in combination with each other.

Accordingly, the transistor TR including the active pattern ACT, the gate electrode GE, the first electrode SD1, and the second electrode SD2 may be arranged on the substrate SUB.

The via insulating layer VIA may be arranged on the first and second electrodes SD1 and SD2, and may cover the first and second electrodes SD1 and SD2. The via insulating layer VIA may include an organic material such as, for example, phenol resin, acrylic resin, polyimide resin, polyamide resin, siloxane resin, epoxy resin, or the like. These may be used alone or in combination with each other.

The pixel electrode PE may be arranged on the via insulating layer VIA. The pixel electrode PE may be connected to the second electrode SD2 (or the first electrode SD1). The pixel electrode PE may include a metal, an alloy, a conductive metal oxide, a conductive metal nitride, a transparent conductive material, or the like. These may be used alone or in combination with each other.

The pixel defining layer PDL may be arranged on the via insulating layer VIA, and may cover at least a portion of the pixel electrode PE. The pixel defining layer PDL may define an opening exposing at least a portion of an upper surface of the pixel electrode PE. The pixel defining layer PDL may include an organic material or an inorganic material. For example, the pixel defining layer PDL may include an organic material such as, for example, epoxy resin, siloxane resin, or the like. For example, the pixel defining layer PDL may include an organic material or an inorganic material including a light blocking material having a black color.

The light emitting layer EL may be arranged on the pixel electrode PE. The light emitting layer EL may be arranged on the pixel electrode PE exposed by the pixel defining layer PDL. The light emitting layer EL may include a material which emits light of a selected color.

The common electrode CE may be arranged on the light emitting layer EL. The common electrode CE may include a metal, an alloy, a conductive metal oxide, a conductive metal nitride, a transparent conductive material, or the like. These may be used alone or in combination with each other.

Accordingly, the light emitting element LE including the pixel electrode PE, the light emitting layer EL, and the common electrode CE may be arranged on the substrate SUB. The light emitting element LE may be electrically connected to the transistor TR. The light emitting element LE may generate light corresponding to a driving current provided from the transistor TR. The transistor TR and the light emitting element LE may correspond to the pixels, respectively.

The encapsulation layer TFE may be arranged on the common electrode CE. The encapsulation layer TFE may protect the light emitting element LE from external oxygen, moisture, or the like. The encapsulation layer TFE may include at least one inorganic layer and at least one organic layer. For example, the encapsulation layer TFE may have a structure in which an inorganic layer and an organic layer are alternately stacked.

The cover panel CP may be arranged below the display panel PA. The cover panel CP may cover a lower surface of the display panel PA. The cover panel CP may have a single-layer structure or a multi-layer structure. For example, the cover panel CP may have a structure in which a cushion member, a heat dissipating member, a conductive thin film, or the like are stacked. The cushion member may absorb impact such that the impact is not applied (or is partially applied) to the display panel PA. The heat dissipating member may prevent heat applied to the display panel PA, or may diffuse heat generated from the display panel PA. The conductive thin film may cancel electromagnetic interference such that the electromagnetic interference is not applied to the display panel PA.

The circuit board CB may be arranged below the cover panel CP. Various elements such as, for example, a driver, a processor, or the like which drive the display panel PA may be arranged on the circuit board CB.

In an embodiment, the display device may be applied to a wearable device. For example, the display device may be applied to a watch-type device. However, embodiments of the present disclosure are not limited thereto, and the display device may be applied to various electronic devices.

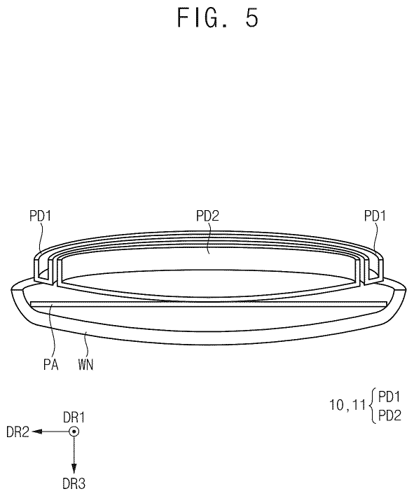

FIGS. 5, 6, 7A, 7B, and 8 are cross-sectional views illustrating a method of manufacturing a display device according to an embodiment of the present disclosure.

For example, a method of manufacturing a display device described with reference to FIGS. 5, 6, 7A, 7B, and 8 may use the pad 10 described with reference to FIGS. 1A and 1B or the pad 11 described with reference to FIGS. 2A and 2B. In some aspects, for example, the method of manufacturing the display device described with reference to FIGS. 5, 6, 7A, 7B, and 8 may be a method of manufacturing the display device described with reference to FIG. 3. Hereinafter, redundant descriptions will be omitted or simplified.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 5, the method may include providing the window WN, the display panel PA, and the pad 10 and the pad 11 including the first pad PD1 and the second pad PD2. For example, the method may include arranging the pad 10 and the pad 11, the display panel PA, and the window WN along the third direction DR3.

In an embodiment, the window WN may have a dome shape. For example, the window WN may extend parallel to the plane defined by the first direction DR1 and the second direction DR2, and may have a dome shape convexly curved in the third direction DR3 in a cross-sectional view. The window WN may define an inner space.

The display panel PA may extend parallel to the plane defined by the first direction DR1 and the second direction DR2. The display panel PA may be accommodated in the inner space of the window WN.

The method may include arranging the pad 10 and the pad 11 on the window WN, and further, arranging the display panel PA such that the display panel PA is between the pad 10 and the pad 11 and the window WN. In an embodiment, the pad 10 and the pad 11 may be provided in a shape corresponding to the window WN. For example, the pads 10 and 11 may extend parallel to the plane defined by the first direction DR1 and the second direction DR2, and the pads 10 and 11 may each have a shape convexly curved in the third direction DR3 in a cross-sectional view.

The pad 10 and the pad 11 may each be of a size which may be accommodated in the inner space of the window WN. The pad 10 and the pad 11 may each include the first pad PD1 and the second pad PD2, and the first pad PD1 and the second pad PD2 may be independently movable in the third direction DR3 and the direction opposite to the third direction DR3.

In an embodiment, the method may include providing the first pad PD1 such that the first pad PD1 corresponds to an edge area (at least a portion of an edge area in the case of the pad 11 of FIGS. 2A and 2B) of the display panel PA, and the method may include providing the second pad PD2 such that the second pad PD2 corresponds to a central area other than the edge area of the display panel PA. That is, the first pad PD1 may be moved in the third direction DR3 such that the first pad PD1 is in contact with the edge area of the display panel PA, and the second pad PD2 may be moved in the third direction DR3 such that the second pad PD2 is in contact with the central area of the display panel PA. Expressed another way, the first pad PD1 may be movable in the third direction DR3 such that the first pad PD1 is in contact with the edge area of the display panel PA, and the second pad PD2 may be movable in the third direction DR3 such that the second pad PD2 is in contact with the central area of the display panel PA. Descriptions herein of the first pad PD1 or the second pad PD2 moving or being moved in a direction may include moving the first pad PD1 or the second pad PD2 by using equipment (not illustrated) or manual techniques in a manufacturing process described herein.

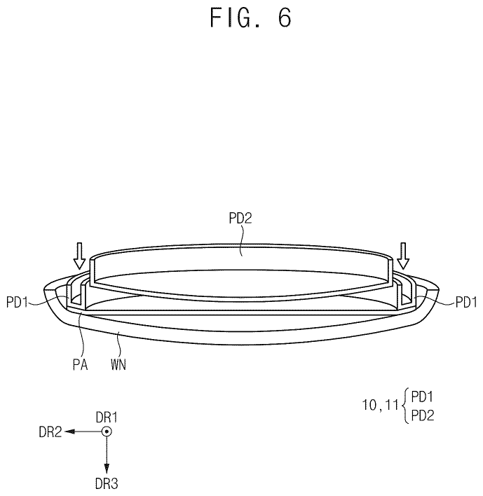

Referring to FIG. 6, the method may include moving the first pad PD1 of the pad 10 and the pad 11 in the third direction DR3 such that the first pad PD1 is in contact with the display panel PA. The first pad PD1 may apply pressure to the edge area of the display panel PA.

When the first pad PD1 applies pressure to the display panel PA, as the display panel PA comes into close contact with the window WN, the edge area of the display panel PA may bend such that the edge area corresponds to the shape of the window WN and is in contact with the window WN.

The first pad PD1 may bond the edge area of the display panel PA to the window WN. In this case, since the first hardness and the first friction coefficient of the first pad PD1 are relatively large and the first thickness TH1 of the first pad PD1 which contacts the display panel PA is relatively small, the edge area of the display panel PA may be fixed to the window WN without being pushed or slipped from the window WN. In other words, the first pad PD1 may firmly fix the edge area of the display panel PA to the window WN.

When the first hardness or the first friction coefficient of the first pad PD1 is relatively small, or the first thickness TH1 of the first pad PD1 which contacts the display panel PA is relatively large, even if the first pad PD1 applies pressure to the edge area of the display panel PA, the edge area of the display panel PA may not be firmly fixed to the window WD, and may be slipped from the first pad PD1 (or from the window WD) or may be pushed by the first pad PD1 (or from the window WD), so that wrinkles may occur in the edge area of the display panel PA.

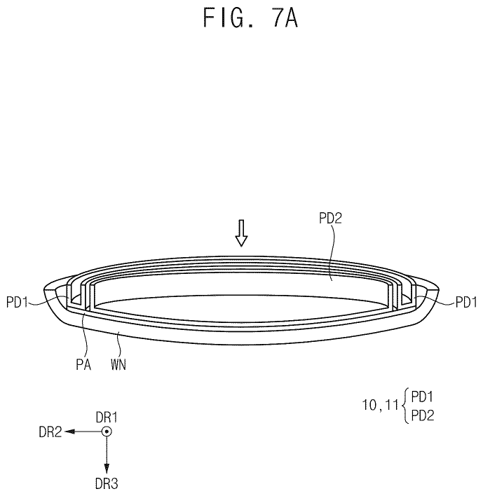

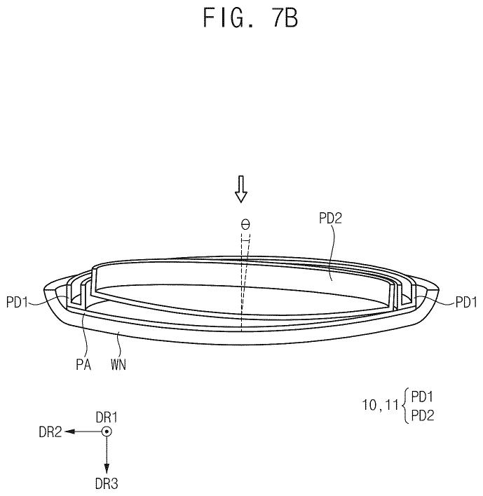

Referring to FIG. 7A, the method may include moving the second pad PD2 of the pad 10 and the pad 11 in the third direction DR3 such that the second pad PD2 is in contact with the display panel PA. The first pad PD1 may apply pressure to the central area of the display panel PA.

When the second pad PD2 applies pressure to the display panel PA, as the display panel PA comes into close contact with the window WN, the central area of the display panel PA may bend such that the central area corresponds to the shape of the window WN and is in contact with the window WN.

The second pad PD2 may bond the central area of the display panel PA to the window WN. In this case, since the first pad PD1 fixes the edge area of the display panel PA to the window WN, the second pad PD2 may stretch the central area of the display panel PA such that at least the central area is bonded to the window WN.

That is, fixing the edge area of the display panel PA with the first pad PD1 and then stretching the central area of the display panel PA with the second pad PD2 may prevent wrinkles from occurring in the edge area of the display panel PA while applying pressure to the display panel PA with the pad 10 and the pad 11. For example, wrinkles occurring in the edge area of the display panel PA may be eliminated entirely, minimized in quantity, or reduced in size.

In an embodiment, referring further to FIG. 7B, the method may include tilting the second pad PD2 and moving the second pad PD2 in the third direction DR3 such that the second pad PD2 is in contact with the display panel PA. For example, the method may include moving the second pad PD2 by tilting the second pad PD2 by an angle of about θ° with respect to a virtual line parallel to the third direction DR3. For example, the second pad PD2 may be the second pad PD2 of the pad 10 described with reference to FIGS. 1A and 1B. However, embodiments of the present disclosure are not limited thereto, and the second pad PD2 may be the second pad PD2 of the pad 11 described with reference to FIGS. 2A and 2B.

Tilting the second pad PD2 such that the second pad PD2 applies pressure to the display panel PA may prevent or minimize air bubbles from occurring between the display panel PA and the window WN during the bonding process. In an example in which the second pad PD2 is tilted and applies pressure to the display panel PA, air bubbles which may occur between the display panel PA and the window WN during the bonding process may be removed by the tilted second pad PD2.

Accordingly, the display panel PA may be bonded to the window WN in a shape corresponding to the window WN. For example, the display panel PA may be bonded to the window WN in a shape convexly curved in the third direction DR3 in a cross-sectional view. The display panel PA may have a selected curvature along the inner surface of the window WN.

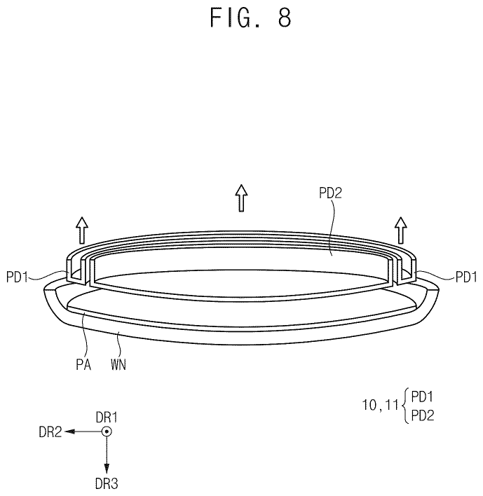

Referring to FIG. 8, the method may include moving the pad 10 and the pad 11 in the direction opposite to the third direction DR3. The method may include moving the first pad PD1 and the second pad PD2 together in the direction opposite to the third direction DR3.

That is, after the display panel PA is bonded to the window WN, the method may include removing the pad 10 and the pad 11. Accordingly, the display panel PA with minimized wrinkles in the edge area may be coupled with the window WN.

In the method of manufacturing the display device according to an embodiment of the present disclosure, after at least a portion of the edge area of the display panel PA is bonded to the window WN using the first pad PD1, the method may include bonding the central area of the display panel PA to the window WN using the second pad PD2. After positioning the first pad PD1 such that the first pad PD1 fixes at least a portion of the edge area of the display panel PA, the method may include positioning or tilting the second pad PD2 such that the second pad PD2 stretches the central area of the display panel PA. Accordingly, for example, a display device may be manufactured while mitigating defects (e.g., preventing defects, reducing the number of defects, reducing the size of the defects, or the like) such as, for example, wrinkles which may occur when applying pressure to the display panel PA with the pad 10 and the pad 11 in a lamination process.

The display device according to an embodiment of the present disclosure may be applied to various electronic devices. An electronic device according to an embodiment of the present disclosure may include the display device described herein, and may further include a module or device having additional functions in addition to the display device.

The present disclosure can be applied to a method of manufacturing various display devices and electronic devices. For example, the present disclosure is applicable to a method of manufacturing various display devices such as, for example, display devices for vehicles, ships and aircraft, portable communication devices, display devices for exhibition or information transmission, medical display devices, and the like.

The foregoing is illustrative of embodiments and is not to be construed as limiting thereof. Although example embodiments have been described, those skilled in the art will readily appreciate that many modifications are possible in the embodiments without materially departing from the novel teachings and advantages of the embodiments of the present disclosure. Accordingly, all such modifications are intended to be included within the scope of the embodiments of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A pad for lamination comprising:
a first pad which applies a first pressure to a first area of a display panel; and
a second pad which is at least partially surrounded by the first pad in a plan view and applies a second pressure to a second area different from the first area of the display panel.

2. The pad of claim 1, wherein:
the first area is an edge area of the display panel, and
the second area is a central area of the display panel.

3. The pad of claim 1, wherein the first pad and the second pad are spaced apart from each other.

4. The pad of claim 1, wherein:
the first pad has a first hardness, and
the second pad has a second hardness different from the first hardness.

5. The pad of claim 1, wherein:
the first pad has a first friction coefficient, and
the second pad has a second friction coefficient different from the first friction coefficient.

6. The pad of claim 1, wherein the first pad completely surrounds the second pad in the plan view.

7. The pad of claim 1, wherein the first pad defines an opening exposing at least a portion of a side surface of the second pad.

8. The pad of claim 1, wherein the first pad and the second pad sequentially apply the first pressure and the second pressure to the display panel.

9. A method of manufacturing a display device, the method comprising:
arranging a pad for lamination on a window and a display panel between the pad and the window;
applying a first pressure to a first area of the display panel with a first pad of the pad, wherein applying the first pressure bonds the first area of the display panel and the window; and
applying a second pressure to a second area different from the first area of the display panel with a second pad of the pad, wherein applying the second pressure bonds the second area of the display panel and the window.

10. The method of claim 9, wherein the applying of the first pressure to the first area of the display panel with the first pad and the applying of the second pressure to the second area of the display panel with the second pad are sequentially performed.

11. The method of claim 9, wherein:
the first area is an edge area of the display panel, and
the second area is a central area of the display panel.

12. The method of claim 9, wherein in the applying of the first pressure to the first area of the display panel with the first pad,
the first area of the display panel is fixed to the window by the first pad.

13. The method of claim 9, wherein in the applying of the second pressure to the second area of the display panel with the second pad,
the second area of the display panel is stretched by the second pad and bonded to the window.

14. The method of claim 9, wherein the first pad surrounds at least a portion of the second pad in a plan view.

15. The method of claim 9, wherein the first pad completely surrounds the second pad in a plan view.

16. The method of claim 9, wherein the first pad defines an opening exposing at least a portion of a side surface of the second pad.

17. The method of claim 9, wherein:
the first pad has a first hardness, and
the second pad has a second hardness different from the first hardness.

18. The method of claim 9, wherein:
the first pad has a first friction coefficient, and
the second pad has a second friction coefficient different from the first friction coefficient.

19. The method of claim 9, wherein the applying of the second pressure to the second area of the display panel with the second pad comprises tilting the second pad in association with applying the second pressure to the second area of the display panel.

20. The method of claim 9, wherein the window has a dome shape convexly curved in a direction.
